(19) United States
(12) Patent Application Publication
(10) Pub. No.: US 2019/0304797 A1
(43) Pub. Date: Oct. 3, 2019

(54) METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: KOKUSAI ELECTRIC CORPORATION, Tokyo (JP)

(72) Inventor: Motomu DEGAI, Toyama-shi (JP)

(73) Assignee: KOKUSAI ELECTRIC CORPORATION, Tokyo (JP)

(21) Appl. No.: 16/294,224

(22) Filed: Mar. 6, 2019

(30) Foreign Application Priority Data
Mar. 27, 2018 (JP) 2018-060070

(51) Int. Cl. H01L 21/311; H01L 21/67; H01L 21/28

(52) U.S. Cl. CPC H01L 21/31122; H01L 21/28185; H01L 21/67103; H01L 21/67069

(57) ABSTRACT

Described herein is a technique capable of processing a film with a high dielectric constant with high accuracy. According to one aspect of the technique described herein, there is provided a method of manufacturing a semiconductor device including: (a) forming a metal fluoride film on a substrate on which a metal oxide film is exposed by supplying a fluorine-containing gas to the substrate and fluoridizing the metal oxide film; and (b) chloridizing and volatilizing the metal fluoride film by supplying a chlorine-containing gas to the substrate on which the metal fluoride film is formed.

### CROSS-REFERENCE TO RELATED PATENT APPLICATION

This non-provisional U.S. patent application claims priority under 35 U.S.C. § 119 of Japanese Patent Application No. 2018-060070, filed on Mar. 27, 2018, in the Japanese Patent Office, the entire contents of which are hereby incorporated by reference.

### BACKGROUND

### 1. Field

The present disclosure relates to a method of manufacturing a semiconductor device, a substrate processing apparatus and a non-transitory computer-readable recording medium.

### 2. Description of the Related Art

Recently, a film with a high dielectric constant may be used to improve the performance of a device such as a semiconductor device.

### SUMMARY

Described herein is a technique capable of processing a film with a high dielectric constant with high accuracy.

According to one aspect of the technique described herein, there is provided a method of manufacturing a semiconductor device including: (a) forming a metal fluoride film on a substrate on which a metal oxide film is exposed by supplying a fluorine-containing gas to the substrate and fluoridizing the metal oxide film; and (b) chloridizing and volatilizing the metal fluoride film by supplying a chlorine-containing gas to the substrate on which the metal fluoride film is formed.

### BRIEF DESCRIPTION OF THE DRAWINGS

FIG. 1 schematically illustrates a vertical cross-section of a vertical type process furnace of a substrate processing apparatus according to one or more embodiments described herein.

FIG. 2 schematically illustrates a cross-section taken along the line A-A of the vertical type process furnace of the substrate processing apparatus shown in FIG. 1.

FIG. 3 is a block diagram schematically illustrating a configuration of a controller and components controlled by the controller of the substrate processing apparatus according to the embodiments.

FIG. 4 is a timing diagram illustrating a gas supply according to the embodiments.

FIGS. 5A through 5D schematically illustrate a surface of a metal oxide film when the metal oxide film is etched using WF₆ and TiCl₄.

FIG. 6 illustrates boiling points of a fluorine compound MF₄ and a chlorine compound MCl₄ when a metal element M is hafnium (Hf) or zirconium (Zr).

FIG. 7A illustrates amounts of film thickness variation when WF₆ and TiCl₄ are alternately and repeatedly supplied, FIG. 7B illustrates amounts of film thickness variation when only WF₆ is repeatedly supplied, and FIG. 7C illustrates amounts of film thickness variation when only TiCl₄ is repeatedly supplied.

FIG. 8 is a timing diagram illustrating a gas supply according to a first modified example of the embodiments described herein.

FIG. 9 is a timing diagram illustrating a gas supply according to a second modified example of the embodiments described herein.

FIG. 10 is a timing diagram illustrating a gas supply according to a third modified example of the embodiments described herein.

FIG. 11 schematically illustrates an exemplary electrode structure used in a logic circuit.

### DETAILED DESCRIPTION

### Embodiments

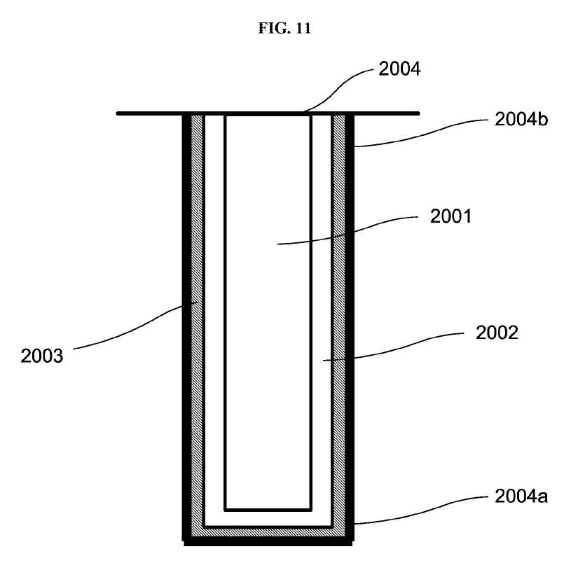

First, an example of a film formed using the technique described herein will be described with reference to FIG. 11. FIG. 11 schematically illustrates an exemplary electrode structure used in a logic circuit. An electrode 2001 is constituted by a metal film containing a metal element such as tungsten (W), for example. An intermediate film 2002 has a work function and is made of, for example, titanium nitride (TiN). A gate insulating film 2003 is made of, for example, a metal oxide film with a high dielectric constant. As the metal oxide film, a hafnium oxide (HfO₂) film or a zirconium oxide (ZrO₂) film, which are described later, may be used.

According to recent trend of high integration of the semiconductor devices, the electrode 2001, the intermediate film 2002 and the gate insulating film 2003 are formed in a deep groove 2004. Specifically, the gate insulating film 2003, the intermediate film 2002 and the electrode 2001 are formed in the deep groove 2004 from a side wall surface toward a center of the deep groove 2004. For simplification, components such as a base film (underlying film) are omitted in FIG. 11.

In order to improve the performance of the semiconductor device, for example, to improve the resistance value of the semiconductor device, a method of making the characteristics of the film uniform may be used. To make the characteristics of the film uniform, for example, the film is formed so as to have a uniform thickness between a deep portion 2004a of the deep groove 2004 (that is, the bottom of the deep groove 2004) and a shallow portion 2004b of the deep groove 2004 (that is, the surface of the deep groove 2004).

An etching process may be used to form the film. According to the etching process with an etching gas, an etched amount depends on conditions such as an exposure amount of the etching gas (a partial pressure of the etching gas in a space) and the time duration of the exposure of the etching gas. Therefore, when a pressure distribution of the etching gas in a process chamber varies, the etched amount varies depending on the position in the process chamber. That is, since it is difficult to supply the etching gas into the deep groove 2004 when etching the film, the etched amount of the film in the deep groove 2004 is smaller than that of the film outside the deep groove 2004.

In addition, recently, in order to increase the capacitance of the electrode, a film with a high dielectric constant may be used as the metal oxide film used for the gate insulating film, or the metal oxide film may be formed thin.

The technique capable of improving the controllability of the etched amount will be described by way of one or more embodiments. According to the technique, it is possible to make the characteristics of the film uniform while realizing thinning of the metal oxide film.

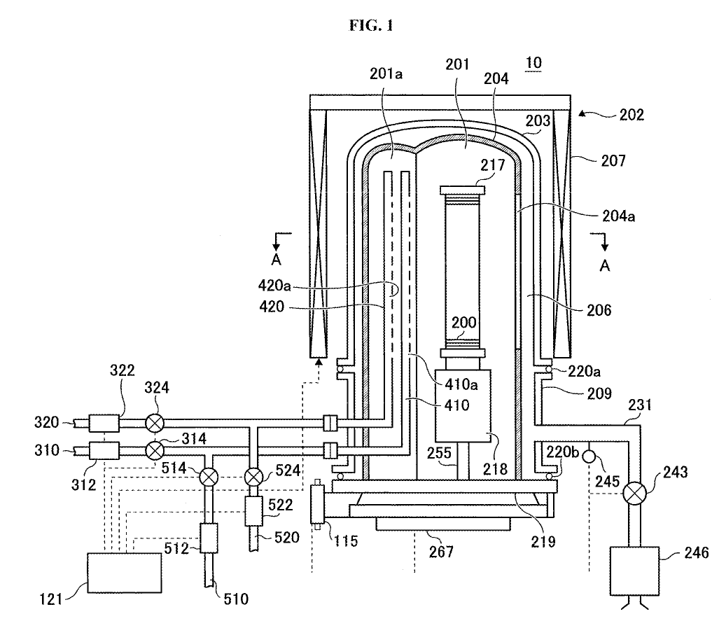

Hereinafter, the technique capable of uniformly etching the metal oxide film will be described with reference to FIGS. 1 through 4. A substrate processing apparatus 10 is an example of an apparatus used in manufacturing processes of the semiconductor device.

### (1) Configuration of Substrate Processing Apparatus

The substrate processing apparatus 10 includes a process furnace 202. The process furnace 202 is provided with a heater 207 serving as a heating apparatus (also referred to as a “heating mechanism” or a “heating system”). The heater 207 is cylindrical and provided in vertically upright manner while being supported by a heater base (not shown) serving as a support plate.

An outer tube 203 constituting a reaction vessel (also referred to as a “process vessel”) is provided on an inner side of the heater 207 so as to be concentric with the heater 207. For example, the outer tube 203 is made of a heat resistant material such as quartz (SiO₂) and silicon carbide (SiC). The outer tube 203 is cylindrical with a closed upper end and an open lower end. A manifold (also referred to as an “inlet flange”) 209 is provided under the outer tube 203 so as to be concentric with the outer tube 203. For example, the manifold 209 is made of a metal such as stainless steel (SUS). The manifold 209 is cylindrical with open upper and lower ends. An O-ring 220a serving as a sealing part is provided between the upper end of the manifold 209 and the outer tube 203. As the manifold 209 is supported by the heater base, the reaction tube 203 is installed to be perpendicular to the heater 207.

An inner tube 204 constituting the reaction vessel is provided on an inner side of the outer tube 203. The inner tube 204 is made of a heat resistant material such as quartz (SiO₂) and silicon carbide (SiC). The inner tube 204 is cylindrical with a closed upper end and an open lower end. The process vessel (the reaction vessel) is constituted mainly by the outer tube 203, the inner tube 204 and the manifold 209. A process chamber 201 is provided in a hollow cylindrical portion (an inside of the inner tube 204) of the process vessel.

The process chamber 201 is configured to accommodate vertically arranged wafers including a wafer 200 serving as a substrate in a horizontal orientation in a multistage manner by a boat 217 to be described later.

Nozzles 410 and 420 are provided in the process chamber 201 so as to penetrate sidewalls of the manifold 209 and the inner tube 204. Gas supply pipes 310 and 320 are connected to the nozzles 410 and 420, respectively. However, the process furnace 202 according to the embodiments is not limited thereto.

MFCs (Mass Flow Controllers) 312 and 322 serving as flow rate controllers (flow rate control mechanisms) are sequentially installed at the gas supply pipes 310 and 320, respectively, from the upstream sides to the downstream sides of the gas supply pipes 310 and 320. Valves 314 and 324 serving as opening/closing valves are sequentially installed at the gas supply pipes 310 and 320, respectively, from the upstream sides to the downstream sides of the gas supply pipes 310 and 320. Gas supply pipes 510 and 520 configured to supply an inert gas are connected to the gas supply pipes 310 and 320 at the downstream sides of the valves 314 and 324, respectively. MFCs 512 and 522 serving as flow rate controllers (flow rate control mechanisms) and valves 514 and 524 serving as opening/closing valves are sequentially installed at the gas supply pipes 510 and 520, respectively, from the upstream sides to the downstream sides of the gas supply pipes 510 and 520.

The nozzles 410 and 420 are connected to front ends of the gas supply pipes 310 and 320, respectively. The nozzles 410 and 420 may include L-shaped nozzles. Horizontal portions of the nozzles 410 and 420 are installed through sidewalls of the manifold 209 and the inner tube 204. Vertical portions of the nozzles 410 and 420 protrude from the inner tube 204 and are installed in a spare chamber 201a having a channel shape (a groove shape) extending in the vertical direction. That is, the vertical portions of the nozzles 410 and 420 are installed in the spare chamber 201a toward the top of the inner tube 204 (in the direction in which the wafers including the 200 are stacked) and along inner walls of the inner tube 204.

The nozzles 410 and 420 extend from a lower region of the process chamber 201 to an upper region of the process chamber 201. The nozzles 410 and 420 are provided with gas supply holes 410a and gas supply holes 420a facing the wafers including the 200, respectively, such that the process gases are supplied to the wafers through the gas supply holes 410a and 420a of the nozzles 410 and 420. The gas supply holes 410a and 420a are provided so as to correspond to a lower region to an upper region of the inner tube 204, and have the same opening area and the same pitch. However, the gas supply holes 410a and 420a are not limited thereto. The opening areas of the gas supply holes 410a and 420a may gradually increase from the lower region toward the upper region of the inner tube 204 to maintain the uniformity of the amounts of gases supplied through the gas supply holes 410a and 420a.

The gas supply holes 410a and 420a of the nozzles 410 and 420 are provided to correspond to a lower portion to an upper portion of the boat 217 to be described later. Therefore, the process gases supplied into the process chamber 201 through the gas supply holes 410a and 420a of the nozzles 410 and 420 are supplied onto the wafers including the wafer 200 accommodated in the boat 217 from the lower portion to the upper portion thereof, that is, the entirety of the wafers accommodated in the boat 217. The nozzles 410 and 420 extend from the lower region to the upper region of the process chamber 201. However, the nozzles 410 and 420 may extend only to the vicinity of a ceiling of the boat 217.

A fluorine-containing gas containing a fluorine (F) element such as tungsten hexafluoride (WF₆), which is one of the process gases, is supplied into the process chamber 201 through the gas supply pipe 310 provided with the MFC 312 and the valve 314 and the nozzle 410.

A chlorine-containing gas containing a chlorine (CI) element such as titanium tetrachloride (TiCl₄), which is one of the process gases, is supplied into the process chamber 201 through the gas supply pipe 320 provided with the MFC 322 and the valve 324 and the nozzle 420.

An inert gas such as nitrogen (N₂) gas is supplied into the process chamber 201 via the gas supply pipes 510 and 520 provided with the MFCs 512 and 522 and the valves 514 and 524 and the nozzles 410 and 420, respectively. While the embodiments will be described by way of an example in which the N₂ gas is used as the inert gas, the inert gas according to the embodiments is not limited thereto. For example, rare gases such as argon (Ar) gas, helium (He) gas, neon (Ne) gas and xenon (Xe) gas may be used as the inert gas instead of the N₂ gas.

While a process gas supply system may be constituted mainly by the gas supply pipes 310 and 320, the MFCs 312 and 322, the valves 314 and 324 and the nozzles 410 and 420, only the nozzles 410 and 420 may be considered as the process gas supply system. The process gas supply system may be simply referred to as a “gas supply system”. An inert gas supply system may be constituted mainly by the gas supply pipes 510 and 520, the MFCs 512 and 522 and the valves 514 and 524.

The gas supply pipe 310, the MFC 312, the valve 314 and the nozzle 410 of the process gas supply system, that is, components configured to supply the fluorine-containing gas to the process chamber 201 may be collectively referred to as a “first gas supply system” or a “fluorine-containing gas supply system”.

The gas supply pipe 320, the MFC 322, the valve 324 and the nozzle 420 of the process gas supply system, that is, components configured to supply the chlorine-containing gas to the process chamber 201 may be collectively referred to as a “second gas supply system” or a “chlorine-containing gas supply system”.

According to the embodiments, a gas is supplied into a vertically long annular space which is defined by the inner wall of the inner tube 204 and the edges (peripheries) of the wafers including the wafer 200 through the nozzles 410 and 420 provided in the spare chamber 201a. The gas is injected into the inner tube 204 around the wafers through the gas supply holes 410a and 420a provided at the nozzles 410 and 420 and facing the wafers, respectively. Specifically, the process gases such as the fluorine-containing gas and the chlorine-containing gas are injected into the inner tube 204 in a direction parallel to the surfaces of the wafers including the wafer 200 through the gas supply holes 410a and 420a of the nozzles 410 and 420, respectively.

An exhaust hole (exhaust port) 204a facing the nozzles 410 and 420 is provided in the sidewall of the inner tube 204 opposite to the spare chamber 201a. For example, the exhaust hole 204a may have a narrow slit-shape elongating vertically. The gas supplied into the process chamber 201 through the gas supply holes 410a and 420a of the nozzles 410 and 420 flows through the surfaces of the wafers including the wafer 200, and then is exhausted through the exhaust hole 204a into an exhaust channel 206 which is a gap provided between the inner tube 204 and the outer tube 203. The gas flowing in the exhaust channel 206 flows into an exhaust pipe 231 and is then discharged out of the process furnace 202.

The exhaust hole 204a is provided to face the wafers including the wafer 200. The gas supplied in the vicinity of the wafers in the process chamber 201 through the gas supply holes 410a and 420a flows in the horizontal direction (that is, a direction parallel to the surfaces of the wafers), and then is exhausted through the exhaust hole 204a into the exhaust channel 206. The exhaust hole 204a is not limited to a slit-shaped through-hole. For example, the exhaust hole 204a may include a plurality of holes.

The exhaust pipe 231 configured to exhaust an inner atmosphere of the process chamber 201 is provided at the manifold 209. A vacuum pump 246 serving as a vacuum exhaust apparatus is connected to the exhaust pipe 231 through a pressure sensor 245 and an APC (Automatic Pressure Controller) valve 243. The pressure sensor 245 serves as a pressure detector (pressure detection mechanism) to detect an inner pressure of the process chamber 201. With the vacuum pump 246 in operation, the APC valve 243 may be opened/closed to vacuum-exhaust the process chamber 201 or stop the vacuum exhaust. With the vacuum pump 246 in operation, the opening degree of the APC valve 243 may be adjusted in order to control the inner pressure of the process chamber 201. An exhaust system may be constituted mainly by the exhaust hole 204a, the exhaust channel 206, the exhaust pipe 231, the APC valve 243 and the pressure sensor 245. The exhaust system may further include the vacuum pump 246.

A seal cap 219, serving as a furnace opening cover capable of sealing a lower end opening of the manifold 209 in airtight manner, is provided under the manifold 209. The seal cap 219 is in contact with the lower end of the manifold 209 from thereunder. The seal cap 219 is made of a metal such as SUS, and is disk-shaped. An O-ring 220b, serving as a sealing part and being in contact with the lower end of the manifold 209, is provided on an upper surface of the seal cap 219. A rotating mechanism 267 configured to rotate the boat 217 accommodating the wafers including the wafer 200 is provided at the seal cap 219 opposite to the process chamber 201. A rotating shaft 255 of the rotating mechanism 267 is connected to the boat 217 through the seal cap 219. As the rotating mechanism 267 rotates the boat 217, the wafers including the wafer 200 are rotated. The seal cap 219 may be moved upward/downward in the vertical direction by a boat elevator 115 provided outside the outer tube 203 in vertically upright manner and serving as an elevating mechanism. When the seal cap 219 is moved upward/downward by the boat elevator 115, the boat 217 may be loaded into the process chamber 201 or unloaded out of the process chamber 201. The boat elevator 115 serves as a transfer device (transfer mechanism) that loads the boat 217, that is, the wafers including the wafer 200 into the process chamber 201 or unloads the boat 217, that is, the wafers including the wafer 200 out of the process chamber 201.

The boat 217 serving as a substrate retainer supports the wafers including the wafer 200, (for example, 25 to 200 wafers), which are concentrically arranged in the vertical direction and in horizontally orientation. The boat 217 is made of a heat resistant material such as quartz and SiC. An insulating plate 218 is provided under the boat 217 in multi-stages. The insulating plate 218 is made of a heat resistant material such as quartz and SiC. The insulating plate 218 suppresses the transmission of heat from the heater 207 to the seal cap 219. However, the embodiments are not limited thereto. For example, instead of the insulating plate 218, a heat insulating cylinder (not shown) may be provided as a cylindrical part made of a heat resistant material such as quartz and SiC.

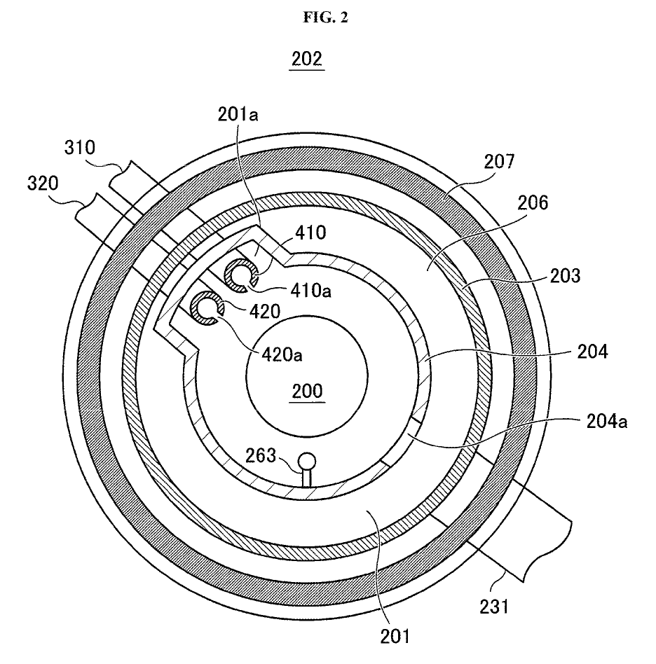

As shown in FIG. 2, a temperature sensor 263 serving as a temperature detector is installed in the inner tube 204. The amount of current supplied to the heater 207 is adjusted based on the temperature detected by the temperature sensor 263 such that the inner temperature of the process chamber 201 has a desired temperature distribution. The temperature sensor 263 is L-shaped like the nozzles 410 and 420, and is provided along the inner wall of the inner tube 204.

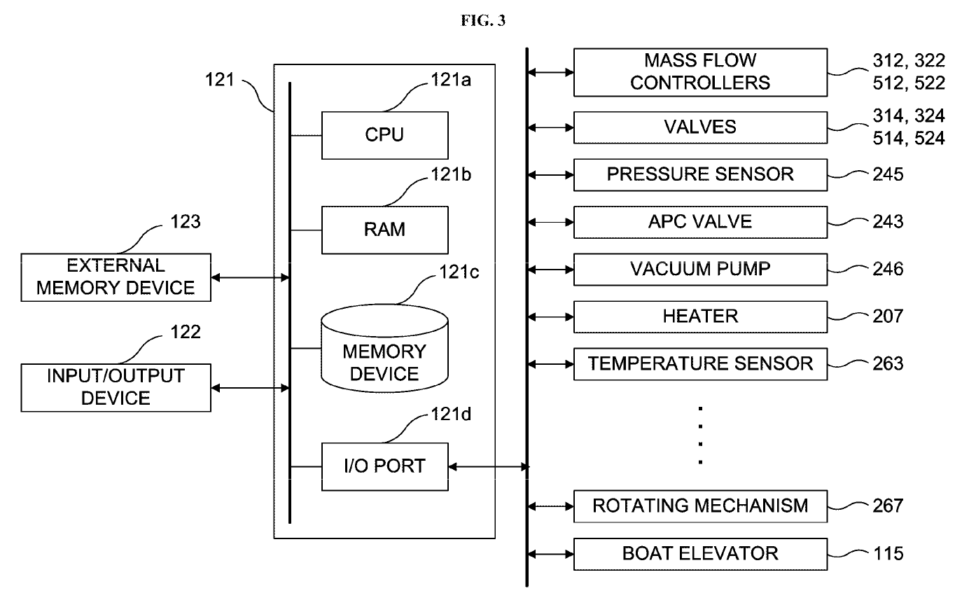

As shown in FIG. 3, a controller 121 serving as a control device (control mechanism) is embodied by a computer including a CPU (Central Processing Unit) 121a, a RAM (Random Access Memory) 121b, a memory device 121c and an I/O port 121d. The RAM 121b, the memory device 121c and the I/O port 121d may exchange data with the CPU 121a through an internal bus. For example, an input/output device 122 such as a touch panel is connected to the controller 121.

The memory device 121c is embodied by components such as a flash memory and HDD (Hard Disk Drive). A control program for controlling the operation of the substrate processing apparatus 10 or a process recipe containing information on the sequences and conditions of a method of manufacturing a semiconductor device described later is readably stored in the memory device 121c. The process recipe is obtained by combining steps of the method of manufacturing the semiconductor device described later such that the controller 121 can execute the steps to acquire a predetermine result, and functions as a program. Hereafter, the process recipe and the control program are collectively referred to as a “program”. In the present specification, the term “program” may indicate only the process recipe, indicate only the control program, or indicate both of them. The RAM 121b functions as a work area where a program or data read by the CPU 121a is temporarily stored.

The I/O port 121d is connected to the above-described components such as the MFCs 312, 322, 512 and 522, the valves 314, 324, 514 and 524, the pressure sensor 245, the APC valve 243, the vacuum pump 246, the heater 207, the temperature sensor 263, the rotating mechanism 267 and the boat elevator 115.

The CPU 121a is configured to read the control program from the memory device 121c and execute the read control program. Furthermore, the CPU 121a is configured to read a recipe such as the process recipe from the memory device 121c according to an operation command inputted from the input/output device 122. According to the contents of the read recipe, the CPU 121a may be configured to control various operations such as flow rate adjusting operations for various gases by the MFCs 312, 322, 512 and 522, opening/closing operations of the valves 314, 324, 514 and 524, an opening/closing operation of the APC valve 243, a pressure adjusting operation by the APC valve 243 based on the pressure sensor 245, a temperature adjusting operation of the heater 207 based on the temperature sensor 263, a start and stop of the vacuum pump 246, a rotation operation and rotation speed adjusting operation of the boat 217 by the rotating mechanism 267, an elevating operation of the boat 217 by the boat elevator 115, and a transport operation of the wafer 200 to the boat 217.

The controller 121 may be embodied by installing the above-described program stored in an external memory device 123 into a computer. For example, the external memory device 123 may include a magnetic tape, a magnetic disk such as a hard disk and a flexible disk, an optical disk such as CD and DVD, a magneto-optical disk such as MO, and a semiconductor memory such as a USB memory and a memory card. The memory device 121c or the external memory device 123 may be embodied by a non-transitory computer readable recording medium. Hereafter, the memory device 121c and the external memory device 123 are collectively referred to as recording media. In the present specification, the term “recording media” may indicate only the memory device 121c, indicate only the external memory device 123, and indicate both of the memory device 121c and the external memory device 123. Instead of the external memory device 123, a communication means such as the Internet and a dedicated line may be used to provide the program to the computer.

### (2) Substrate Processing

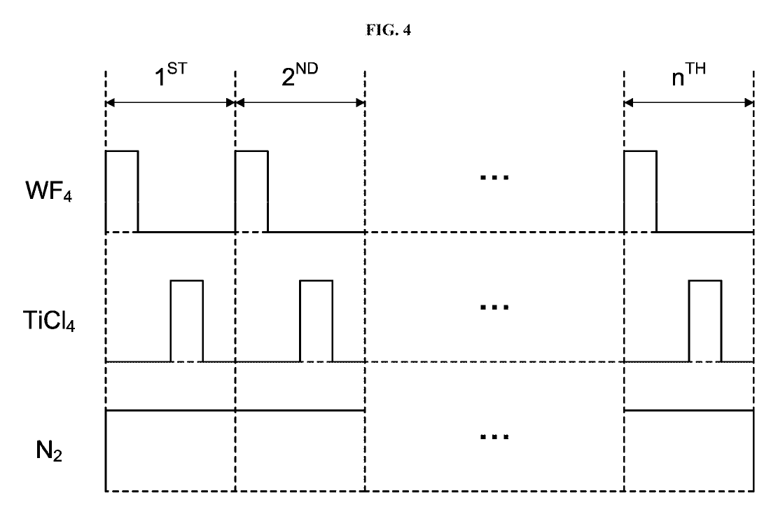

Hereinafter, an exemplary sequence of a substrate processing of etching the surface of the wafer 200 where the metal oxide film containing hafnium oxide (HfO₂) or zirconium oxide (ZrO₂) as a main component is exposed, which is a part of manufacturing processes of the semiconductor device, will be described with reference to FIG. 4. In the following descriptions, the metal element such as hafnium (Hf) and zirconium (Zr) is denoted by M. That is, the metal oxide film in the embodiments is denoted by “MO film”, for example. The exemplary sequence of etching the surface of the wafer 200 where the metal oxide film (MO film) is exposed is performed by using the process furnace 202 of the substrate processing apparatus 10 described above. Hereinafter, the components of the substrate processing apparatus 10 are controlled by the controller 121.

In the substrate processing (manufacturing process of the semiconductor device) according to the embodiments, an etching process of etching the metal oxide film formed on the wafer 200 is performed by sequentially repeating a cycle including: (a) a fluoridation step of forming a metal fluoride film on the wafer 200 on which the metal oxide film (MO film) is exposed by supplying the fluorine-containing gas to the wafer 200 and fluoridizing the metal oxide film; and (b) a volatilization step of chloridizing and volatilizing the metal fluoride film by supplying the chlorine-containing gas to the wafer 200 on which the metal fluoride film is formed.

In the present specification, the term “wafer” may refer to “a wafer itself” or refer to “a wafer and a stacked structure (aggregated structure) of predetermined layers or films formed on the surface of the wafer”. In the present specification, the term “surface of wafer” refers to “a surface (exposed surface) of a wafer” or “the surface of a predetermined layer or a film formed on the wafer”. In the present specification, the terms “substrate” and “wafer” may be used as substantially the same meaning.

<Wafer Loading Step>

The wafers including the wafer 200 are charged into the boat 217 (wafer charging). After the boat 217 is charged with wafers including the wafer 200, the boat 217 supporting the wafers is elevated by the boat elevator 115 and loaded into the process chamber 201 (boat loading), as shown in FIG. 1. With the boat 217 loaded, the seal cap 219 seals the lower end opening of the reaction tube 203 via the O-ring 220b.

<Pressure and Temperature Adjusting Step>

The vacuum pump 246 vacuum-exhausts the process chamber 201 until the inner pressure of the process chamber 201 reaches a desired pressure (vacuum degree). In the pressure and temperature adjusting step, the inner pressure of the process chamber 201 is measured by the pressure sensor 245, and the APC valve 243 is feedback-controlled based on the measured pressure (pressure adjusting). The vacuum pump 246 is continuously operated until at least the processing of the wafer 200 is completed. The heater 207 heats the process chamber 201 such that the inner temperature of the process chamber 201 reaches a desired predetermined temperature. The amount of current supplied to the heater 207 is feedback-controlled based on the temperature detected by the temperature sensor 263 such that the inner temperature of the process chamber 201 has a desired temperature distribution (temperature adjusting). The heater 207 continuously heats the process chamber 201 until at least the processing of the wafer 200 is completed.

<Fluoridation Step (Supplying WF₆ Gas)>

The valve 314 is opened to supply WF₆ gas, which is one of the process gases, into the gas supply pipe 310. A flow rate of the WF₆ gas is adjusted by the MFC 312. The WF₆ gas with the flow rate thereof adjusted is supplied into the process chamber 201 through the gas supply holes 410a of the nozzle 410 to supply the WF₆ gas onto the wafer 200, and then is exhausted through the exhaust pipe 231. Simultaneously, the valve 514 is opened to supply the inert gas such as N₂ gas into the gas supply pipe 510. A flow rate of the N₂ gas is adjusted by the MFC 512. The N₂ gas with the flow rate thereof adjusted is supplied with the WF₆ gas into the process chamber 201, and is exhausted through the exhaust pipe 231. In order to prevent the WF₆ gas from entering the nozzle 420, the valve 524 is opened to supply the N₂ gas into the gas supply pipe 520. The N₂ gas is supplied into the process chamber 201 through the gas supply pipe 320 and the nozzle 420, and is exhausted through the exhaust pipe 231.

In the fluoridation step, the APC valve 243 is appropriately controlled to adjust the inner pressure of the process chamber 201 to a predetermined pressure. For example, the predetermined pressure of the process chamber 201 may range from 1 Pa to 1,000 Pa. The flow rate of the WF₆ gas supplied into the process chamber 201 is adjusted by the MFC 312 to a predetermined flow rate. For example, the predetermined flow rate of the WF₆ gas may range from 5 sccm to 1,000 sccm. For example, the predetermined flow rate of the WF₆ gas is set to 5 sccm. The flow rates of the N₂ gas supplied into the process chamber 201 are adjusted by the MFCs 512 and 522 to predetermined flow rates, respectively. For example, the predetermined flow rates of the N₂ gas supplied into the process chamber 201 may range from 10 sccm to 2,000 sccm, respectively. The temperature of the heater 207 is adjusted such that the temperature of the wafer 200 may become a predetermined temperature. For example, the predetermined temperature of the wafer 200 may range from 200° C. to 400° C. For example, the predetermined temperature of the wafer 200 is set to 250° C.

In the fluoridation step, only the WF₆ gas and the N₂ gas are supplied into the process chamber 201. By supplying the WF₆ gas, the metal oxide film (MO film) on the surface of the wafer 200 is fluoridized and changed into a metal fluoride film (MFₓ film). The chemical reaction of the WF₆ gas and the metal oxide film (MO film) in the fluoridation step may be represented as below:

MO₂+WF₆→MF_{X}+WO_{Y}F_{Z} [Formula 1]

After a predetermined time elapses from the supply of the WF₆ gas, for example, after 10 seconds, the valve 314 of the gas supply pipe 310 is closed to stop the supply of the WF₆ gas. For example, the time duration of supplying the WF₆ gas to the wafer 200 may range from 1 second to 100 seconds.

<First Purging Step (Removing Residual Gas)>

Subsequently, after the supply of the WF₆ gas is stopped, a purging process for exhausting the gas in the process chamber 201 is performed. In the first purging step (exhausting step), with the APC valve 243 of the exhaust pipe 231 open, the vacuum pump 246 vacuum-exhausts the inside of the process chamber 201 to remove a residual WF₆ gas which did not react or WO_{Y}F_{Z} gas after fluoridizing the metal oxide film from the process chamber 201. By maintaining the valves 514 and 524 open, the N₂ gas is continuously supplied into the process chamber 201. The N₂ gas serves as a purge gas, which improves the efficiency of removing the residual WF₆ gas which did not react or the WO_{Y}F_{Z} gas after fluoridizing the metal oxide film from the process chamber 201. The time duration of the first purging step may be, for example, 10 seconds.

<Volatilization Step (Supplying TiCl₄ Gas)>

After the residual gas is removed from the process chamber 201, the valve 324 is opened to supply TiCl₄ gas, which is one of the process gases, into the gas supply pipe 320. A flow rate of the TiCl₄ gas is adjusted by the MFC 322. The TiCl₄ gas with the flow rate thereof adjusted is supplied into the process chamber 201 through the gas supply holes 420a of the nozzle 420 to supply the TiCl₄ gas onto the wafer 200, and then is exhausted through the exhaust pipe 231. Simultaneously, the valve 524 is opened to supply N₂ gas into the gas supply pipe 520. A flow rate of the N₂ gas is adjusted by the MFC 522. The N₂ gas with the flow rate thereof adjusted is supplied with the TiCl₄ gas into the process chamber 201, and is exhausted through the exhaust pipe 231. In order to prevent the TiCl₄ gas from entering the nozzle 410, the valve 514 is opened to supply the N₂ gas into the gas supply pipe 510. The N₂ gas is supplied into the process chamber 201 through the gas supply pipe 310 and the nozzle 410, and is exhausted through the exhaust pipe 231.

In the volatilization step, the APC valve 243 is appropriately controlled to adjust the inner pressure of the process chamber 201 to a predetermined pressure. For example, the predetermined pressure of the process chamber 201 may range from 5 Pa to 1,000 Pa. The flow rate of the TiCl₄ gas supplied into the process chamber 201 is adjusted by the MFC 322 to a predetermined flow rate. For example, the predetermined flow rate of the TiCl₄ gas may range from 3 sccm to 500 sccm. For example, the predetermined flow rate of the TiCl₄ gas is set to 5 sccm. The flow rates of the N₂ gas supplied into the process chamber 201 are adjusted by the MFCs 512 and 522 to predetermined flow rates, respectively. For example, the predetermined flow rates of the N₂ gas supplied into the process chamber 201 may range from 5 sccm to 2,000 sccm, respectively. For example, the time duration of supplying the TiCl₄ gas to the wafer 200 may be 2 seconds. In the volatilization step, the temperature of the heater 207 is adjusted to the same temperature as the fluoridation step (supplying WF₆ gas).

In the volatilization step, only the TiCl₄ gas and the N₂ gas are supplied into the process chamber 201. The TiCl₄ gas chloridizes the metal fluoride film formed on the wafer 200 in the fluoridation step.

The chemical reaction in the volatilization step may be represented as below:

MF₄+TiCl₄→MCl_{A}F_{B}+TiCl_{B}F_{A}, [Formula 2]

wherein A is 1, 2, 3 or 4, and A and B satisfy A+B=4.

The MCl_{A}F_{B} generated on the surface of the metal oxide film by chloridizing the metal fluoride film is volatilized at 250° C. which is the processing temperature of the process chamber 201, and diffuses in the process chamber 201.

<Second Purging Step (Removing Residual Gas)>

Subsequently, after the supply of the TiCl₄ gas is stopped, a purging process for exhausting the gas in the process chamber 201 is performed in the same manners as the first purging step. In the second purging step (exhausting step), with the APC valve 243 of the exhaust pipe 231 open, the vacuum pump 246 vacuum-exhausts the inside of the process chamber 201 to remove a residual TiCl₄ gas which did not react or various gases such as the TiCl_{B}F_{A} gas after chloridizing the metal fluoride film and the MCl_{A}F_{B} gas volatilized on the surface of the metal oxide film from the process chamber 201. By maintaining the valves 514 and 524 open, the N₂ gas is continuously supplied into the process chamber 201. The N₂ gas serves as the purge gas, which improves the efficiency of removing various residual gases such as the residual TiCl₄ gas, the TiCl_{B}F_{A} gas and the MCl_{A}F_{B} gas from the process chamber 201. The time duration of the second purging step may be, for example, 10 seconds.

<Performing a Predetermined Number of Times>

By performing a cycle wherein the fluoridation step, the first purging step, the volatilization step and the second purging step are performed sequentially, the etching process is performed on the metal oxide film exposed on the wafer 200. Preferably, the cycle may be performed at least once, that is, a predetermined number of times (n times, n is a natural number equal to or greater than 1).

That is, according to the etching process of the embodiments, a combination of the fluoridation step and the volatilization step may be performed a plurality of times. According to the embodiments, since the metal oxide film can be removed on a molecular layer basis, it is possible to control the etched amount precisely.

<Purging and Returning to Atmospheric Pressure Step>

The N₂ gas is supplied into the process chamber 201 through each of the gas supply pipes 510 and 520, and then is exhausted through the exhaust pipe 231. The N₂ gas serves as the purge gas. The process chamber 201 is thereby purged such that the residual gas or the by-products remaining in the process chamber 201 is removed from the process chamber 201 (purging). Thereafter, the inner atmosphere of the process chamber 201 is replaced with the inert gas (replacing with inert gas), and the inner pressure of the process chamber 201 is returned to atmospheric pressure (returning to atmospheric pressure).

<Wafer Unloading Step>

Thereafter, the seal cap 219 is lowered by the boat elevator 115 and the lower end of the reaction tube 203 is opened. The boat 217 with the processed wafers including the wafer 200 charged therein is unloaded out of the reaction tube 203 through the lower end of the reaction tube 203 (boat unloading). Then, the processed wafers including the wafer 200 are discharged from the boat 217 (wafer discharging).

That is, after the volatilization step described above, the processed wafers including the wafer 200 are unloaded. Therefore, it is possible to prevent impurities from adding the metal oxide film because no fluoride remains on the wafer 200.

### (3) Mechanism of Etching Using WF₆ and TiCl₄

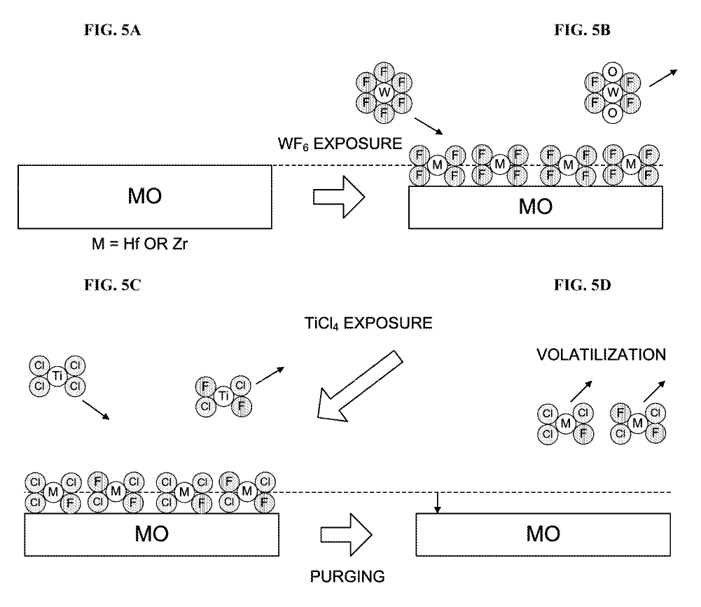

Subsequently, the mechanism of the etching process using the WF₆ and the TiCl₄ described above will be described in detail with reference to FIGS. 5A through 5D.

When the WF₆ gas is supplied to the metal oxide film (MO film) shown in FIG. 5A, it is presumed that a surface layer of the metal oxide film (MO film) is fluoridized by the reaction represented by [Formula 1] described above to form a metal fluoride film (MF₄ film) as shown in FIG. 5B.

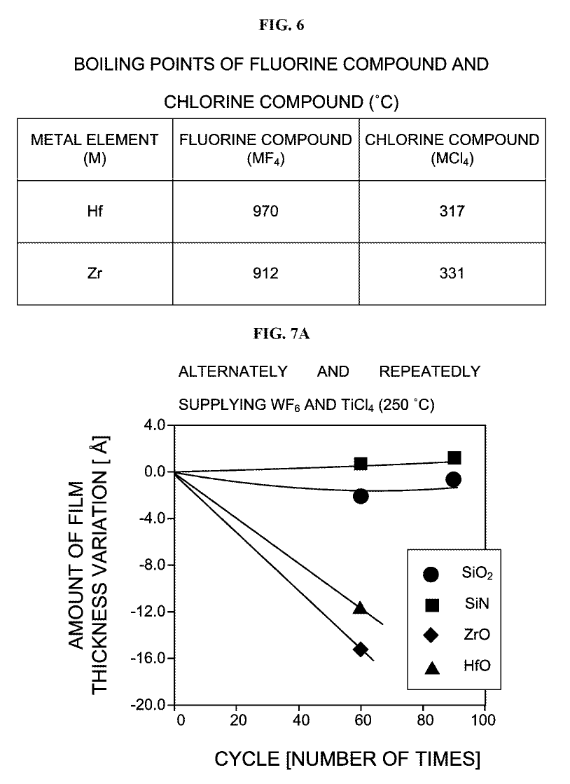

FIG. 6 schematically illustrates boiling points of the fluorine compound MF₄ and the chlorine compound (MCl₄) when the metal element M is hafnium (Hf) or zirconium (Zr).

As shown in FIG. 6, the boiling point of the metal fluoride film (MF₄ film) formed on the surface layer of the metal oxide film (MO film) is, for example, 912° C. when the metal fluoride film is the fluorine compound of zirconium (Zr) and 970° C. when the metal fluoride film is the fluorine compound of hafnium (Hf), which is much higher than the processing temperature of the wafer 200 of 250° C. Therefore, the metal fluoride film (MF₄ film) formed on the surface layer of the metal oxide film (MO film) remains on the surface of the metal oxide film (MO film) without volatilization.

The metal fluoride film (MF₄ film) acts as a diffusion preventing layer of the WF₆ gas. Therefore, when the metal fluoride film (MF₄ film) reaches a certain thickness, the WF₆ gas does not reach the surface of the metal oxide film (MO film). As a result, the fluoridation reaction of the metal oxide film (MO film) is stopped. That is, the thickness of the metal fluoride film (MF₄) generated in the fluoridation step is always constant without being influenced by the conditions such as the exposure amount of the WF₆ gas or the exposure time of the WF₆ gas.

Thereafter, when the metal fluoride film (MF₄ film) is exposed to the TiCl₄ gas, it is presumed that the metal fluoride film (MF₄ film) is chloridized by the reaction represented by [Formula 2] described above to be converted to the MCl_{A}F_{B} as shown in FIG. 5C, which is a chloride.

As shown in FIG. 6, the boiling point of the chloride of hafnium (Hf) or zirconium (Zr) is 317° C. or 331° C., respectively, which is close to the processing temperature of the wafer 200 of 250° C. Therefore, as shown in FIG. 5D, the MCl_{A}F_{B}, which is a chloride of hafnium (Hf) or zirconium (Zr), is volatilized from the surface of the wafer 200 and is separated from the surface of the wafer 200 in a gaseous state. As a result, the metal oxide film (MO film) is exposed on the surface of the wafer 200.

By repeating the steps described above a predetermined number of times, it is presumed that the etching process is performed in a self-inhibiting (self-limiting) or self-controlling manner, that is, in a manner such that the metal oxide film (MO film) is removed by a constant thickness without being affected by the conditions such as the exposure amount of the process gases.

That is, it is possible to etch the metal oxide film (MO film) only a certain thickness (for example, an atomic layer or a molecular layer) with a single etching process with respect to the metal oxide film. Therefore, it is possible to control the etched amount of the film such as the metal oxide film by controlling the number of times the metal oxide film is exposed to the process gases. As a result, according to the etching process of the embodiments, it is possible to improve the controllability of the etched amount.

According to the embodiments, the temperature of the wafer 200 is controlled (adjusted) to be lower than a thermal decomposition temperature of the metal fluoride film (MF₄ film) in the fluoridation step. Thus, it is possible to suppress the MF₄ from self-decomposing due to the heat and volatilizing from the wafer 200. In addition, the temperature of the wafer 200 in the volatilization step is controlled to be higher than a reaction temperature of the chlorine-containing gas and the metal fluoride film. Thus, it is possible to promote the reaction between the chlorine-containing gas and the metal fluoride film.

By setting the temperature of the wafer 200 as described above, the metal fluoride film reacts with the chlorine-containing gas on the surface of the wafer 200. Thus, it is possible to remove the metal fluoride film from the surface of the wafer 200.

When the fluorine-containing gas and the chlorine-containing gas are mixed on the wafer 200, by-products may be generated by the reaction of the fluorine-containing gas and the chlorine-containing gas. When the by-products are generated, the chlorine-containing gas may be physically disturbed by the by-product while the chlorine-containing gas is supplied to the wafer 200. As a result, the volatilization step may not be performed normally. However, according the embodiments, the exhausting step (purging step) of exhausting the atmosphere of the process chamber 201 is provided between the fluoridation step and the volatilization step. Therefore, according to the embodiments, it is possible to reliably supply the chlorine-containing gas to the surface of the wafer 200 by exhausting the fluorine-containing gas before supplying the chlorine-containing gas so as to prevent the by-products from being generated.

The technique described herein may be effectively applied to form a logic device (logic circuit). The reasons are explained below. In the logic device, metal oxide films may be used for a gate insulating film of an electrode and a power supply circuit. The metal oxide films may be formed using the same process.

In general, a gate electrode used in the power supply circuit is configured to thicken the metal oxide film to increase a withstand voltage thereof. However, in order to increase the capacitance as described above, the metal oxide film used for the electrode is required to be thin.

When the etching process according to the embodiments is performed while the gate electrode used for the power supply circuit and the metal oxide film used for the electrode are exposed simultaneously, the gate electrode used for the power supply circuit may be thinned such that and the desired performance of the withstand voltage may not be satisfied.

Therefore, when the gate electrode used for the power supply circuit and the metal oxide film used for the electrode are exposed simultaneously, an etching resistant film is selectively formed on the gate electrode used for the power supply circuit before the etching process according to the embodiments is performed. Thereby, the gate electrode used for the power supply circuit can be thinned while maintaining a desired thickness of the gate electrode.

### (4) Effects According to the Embodiments

According to the embodiments, by supplying the chlorine-containing gas to the wafer 200 after the fluoridation step and reacting the chlorine-containing gas with the metal oxide film on the surface of the wafer 200, it is possible to etch the metal oxide film.

Therefore, according to the embodiments, when the metal oxide film such as the hafnium oxide film (HfO₂ film) and the zirconium oxide film (ZrO₂ film) is etched, the etched amount does not depend on the conditions such as the exposure amount of the etching gas. As a result, it is possible to improve the controllability of the etched amount.

### (5) Experimental Examples

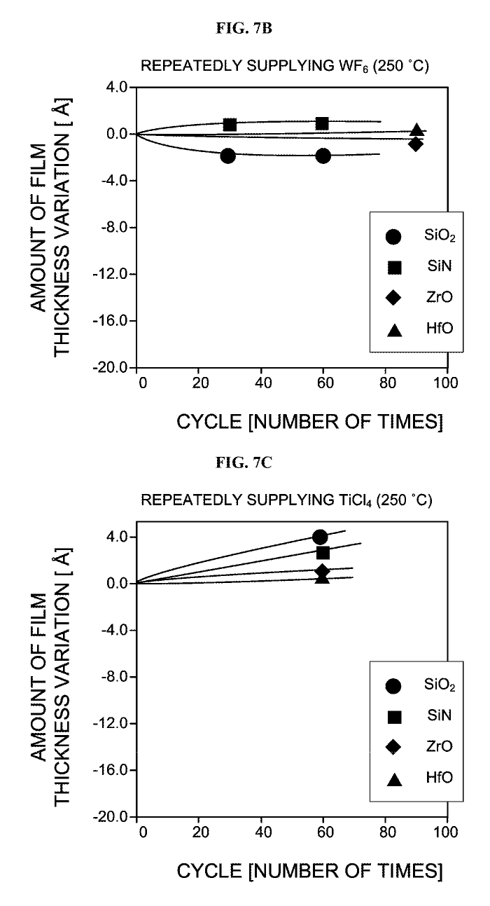

Hereinafter, results of etching the HfO₂ film and the ZrO₂ film by the above-described etching process of performing the fluoridation step, the first purging step, the volatilization step and the second purging step sequentially will be described with reference to FIG. 7A. FIG. 7A illustrates amounts of film thickness variation (that is, the etched amounts) as the results. In FIG. 7A, results of etching the silicon oxide film (SiO₂ film) and the silicon nitride film (SiN film) simultaneously with the HfO₂ film and the ZrO₂ film are also illustrated for comparison.

Referring to FIG. 7A, the HfO₂ film is etched 12 Å and the ZrO₂ film is etched 16 Å when the cycle of the above-described etching process of alternately supplying the WF₆ gas and the TiCl₄ gas is performed 60 times. However, the thicknesses of the SiO₂ film and the SiN film are hardly changed when the cycle is performed 60 times.

In order to confirm the self-inhibiting characteristics of the etching process of the embodiments, results of exposing the respective process gases of the WF₆ gas or the TiCl₄ gas alone to the wafers formed with the HfO₂ film or the ZrO₂ film, respectively, are illustrated in FIGS. 7B and 7C. In FIGS. 7B and 7C, results of exposing the respective process gases of the WF₆ gas or the TiCla gas alone to the wafers formed with the SiO₂ film or the SiN film, respectively, are also illustrated for comparison.

FIG. 7B illustrates amounts of film thickness variation when only the fluoridation step and the first purging step of the etching process of the embodiments are performed alternately and repeatedly.

Referring to FIG. 7B, the thicknesses of the HfO₂ film, the ZrO₂ film, the SiO₂ film and the SiN film are not substantially decreased, regardless of the number of repetitions of the fluoridation step and the first purging step. That is, the HfO₂ film, the ZrO₂ film, the SiO₂ film and the SiN film are hardly etched by the repetition of the fluoridation step and the first purging step.

FIG. 7C schematically illustrates amounts of film thickness variation when only the volatilization step and the second purging step of the etching process of the embodiments are performed alternately and repeatedly. Referring to FIG. 7C, similar to the results shown in FIG. 7B, the thicknesses of the HfO₂ film, the ZrO₂ film, the SiO₂ film and the SiN film are not substantially decreased, regardless of the number of repetitions of the volatilization step and the second purging step. That is, the HfO₂ film, the ZrO₂ film, the SiO₂ film and the SiN film are hardly etched by the repetition of the volatilization step and the second purging step.

Referring to FIGS. 7A through 7C, the HfO₂ film and the ZrO₂ film are not fluoridized or chloridized when the WF₆ gas or the TiCl₄ gas alone is repeatedly supplied to the HfO₂ film or the ZrO₂ film. In addition, it is possible to confirm the self-inhibiting characteristics of the etching process of alternately supplying the WF₆ gas and the TiCl₄ gas according to the embodiments.

### (6) Modified Examples of the Embodiments

### First Modified Example

As shown in FIG. 4, the embodiments are described by way of an example in which the etching process includes the fluoridation step of supplying the TiCl₄ gas and the volatilization step of supplying the TiCl₄ gas. As shown in FIG. 4, the supply of WF₆ gas is performed only once in the fluoridation step and the supply of TiCl₄ gas is performed only once in the volatilization step.

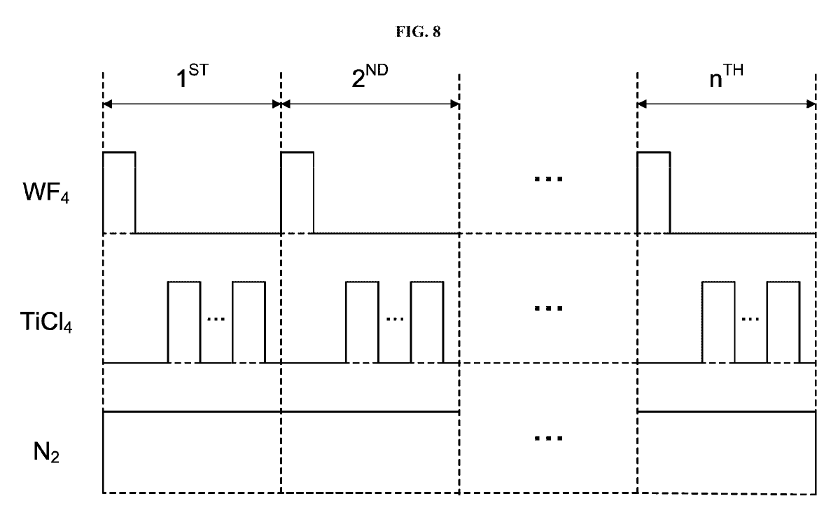

However, according to the first modified example of the embodiments, as shown in FIG. 8, the supply of the WF₆ gas is performed only once in the fluoridation step and the supply of the TiCl₄ gas is performed a plurality of times in the volatilization step. The etching process is performed by alternately repeating the fluoridation step and the volatilization step according to the first modified example.

According to the first modified example, the chlorine-containing gas and the inert gas are alternately supplied to the wafer 200 in the volatilization step. Therefore, according to the first modified example, it is possible to more reliably remove the by-products (for example, the TiCl_{B}F_{A} described above) physically from the surface of the wafer 200. Since the by-products do not adhere to the surface of the metal oxide film, the by-products do not interfere with the etching process. As a result, it is possible to etch the surface of the wafer 200 more uniformly.

### Second Modified Example

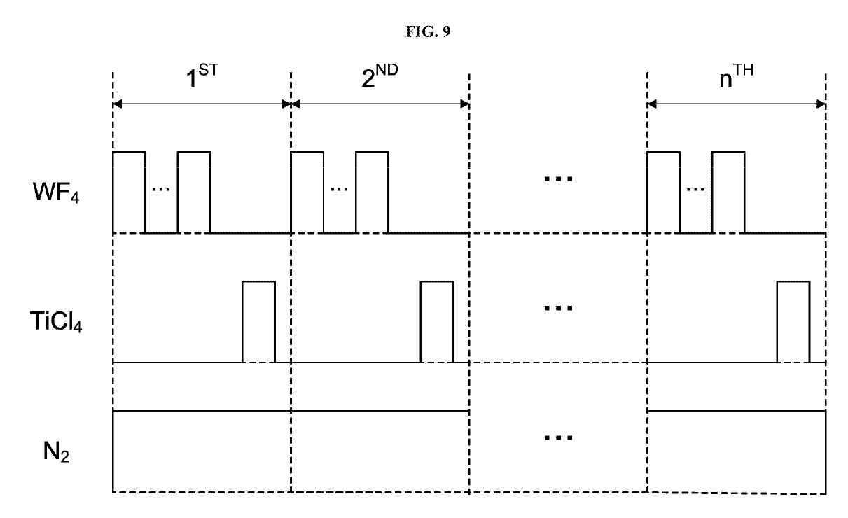

According to the second modified example of the embodiments, as shown in FIG. 9, the supply of the WF₆ gas is performed a plurality of times in the fluoridation step and the supply of the TiCl₄ gas is performed only once in the volatilization step. The etching process is performed by alternately repeating the fluoridation step and the volatilization step according to the second modified example.

According to the second modified example, the fluorine-containing gas and the inert gas are alternately supplied to the wafer 200 in the fluoridation step. Therefore, according to the second modified example, it is possible to more reliably remove the by-products (for example, the WO_{Y}F_{Z} described above) physically from the surface of the wafer 200. Since the by-products do not adhere to the surface of the metal oxide film, the by-products do not interfere with the etching process. As a result, it is possible to etch the surface of the wafer 200 more uniformly.

### Third Modified Example

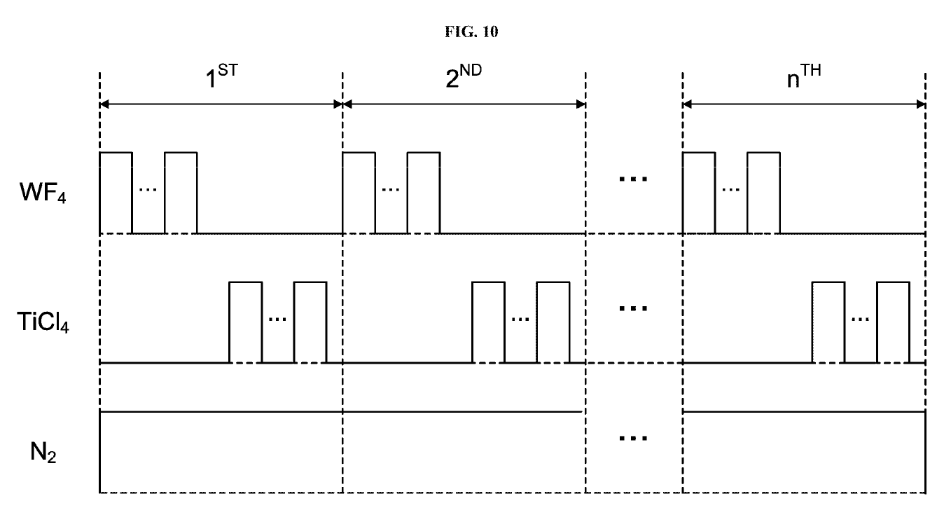

According to the third modified example of the embodiments, as shown in FIG. 10, the supply of the WF₆ gas is performed a plurality of times in the fluoridation step and the supply of the TiCl₄ gas is performed a plurality of times in the volatilization step. The etching process is performed by alternately repeating the fluoridation step and the volatilization step according to the third modified example.

### Other Embodiments

While the embodiments and the modified examples are described by way of an example in which the tungsten hexafluoride (WF₆) gas is used as the fluorine-containing gas, the above-described technique is not limited thereto. For example, the above-described technique may be applied when other gases such as hydrogen fluoride (HF) gas, chlorine trifluoride (ClF₃) gas and fluorine (F₂) gas are used as the fluorine-containing gas.

Similarly, while the embodiments and the modified examples are described by way of an example in which the titanium tetrachloride (TiCl₄) gas is used as the chlorine-containing gas, the above-described technique is not limited thereto. For example, the above-described technique may be applied when other gases such as silicon tetrachloride (SiCl₄) gas, chlorine (Cl₂) gas and hydrogen chloride (HCl) gas are used as the chlorine-containing gas.

In addition, while the embodiments and the modified examples are described by way of an example in which the etching process is performed on the metal oxide film containing hafnium (Hf) or zirconium (Zr) as the metal element, the above-described technique is not limited thereto. For example, the above-described technique may be applied when the etching process is performed on a metal oxide film containing a metal element such as titanium (Ti) and nickel (Ni) instead of hafnium or zirconium.

While the technique is described by way of the above-described embodiments and the modified examples, the above-described technique is not limited thereto. The above-described embodiments and the modified examples may be appropriately combined.

According to the technique described herein, it is possible to process a film with a high dielectric constant with high accuracy.

What is claimed is:

1. A method of manufacturing a semiconductor device, comprising:
(a) forming a metal fluoride film on a substrate on which a metal oxide film is exposed by supplying a fluorine-containing gas to the substrate and fluoridizing the metal oxide film; and
(b) chloridizing and volatilizing the metal fluoride film by supplying a chlorine-containing gas to the substrate on which the metal fluoride film is formed.

2. The method of claim 1, wherein the substrate is heated to a temperature lower than a thermal decomposition temperature of the metal fluoride film in (a).

3. The method of claim 2, wherein the substrate is heated to a temperature higher than a reaction temperature of the chlorine-containing gas and the metal fluoride film in (b).

4. The method of claim 1, further comprising:
(c) exhausting the fluorine-containing gas supplied to the substrate.

5. The method of claim 4, further comprising:
(d) alternately performing (a) and (c).

6. The method of claim 2, further comprising:
(c) exhausting the fluorine-containing gas supplied to the substrate; and
(d) alternately performing (a) and (c).

7. The method of claim 3, further comprising:
(c) exhausting the fluorine-containing gas supplied to the substrate; and
(d) alternately performing (a) and (c).

8. The method of claim 1, further comprising:
(e) exhausting the chlorine-containing gas supplied to the substrate.

9. The method of claim 8, further comprising:
(f) alternately performing (b) and (e).

10. The method of claim 3, further comprising:
(e) exhausting the chlorine-containing gas supplied to the substrate; and
(f) alternately performing (b) and (e).

11. The method of claim 7, further comprising:
(e) exhausting the chlorine-containing gas supplied to the substrate; and
(f) alternately performing (b) and (e).

12. The method of claim 1, further comprising:
(g) etching the metal oxide film formed on the substrate by sequentially repeating (a) and (b) repeatedly.

13. The method of claim 8, further comprising:
(h) supplying an inert gas to the substrate after (b); and
(i) alternately performing (b) and (h).

14. A substrate processing apparatus comprising:
a process chamber where a substrate is accommodated;
a fluorine-containing gas supply system configured to supply a fluorine-containing gas to the process chamber;
a chlorine-containing gas supply system configured to supply a chlorine-containing gas to the process chamber; and
a controller configured to control the fluorine-containing gas supply system and the chlorine-containing gas supply system to perform:
(a) forming a metal fluoride film on the substrate on which a metal oxide film is exposed by supplying the fluorine-containing gas to the substrate and fluoridizing the metal oxide film; and
(b) chloridizing and volatilizing the metal fluoride film by supplying the chlorine-containing gas to the substrate on which the metal fluoride film is formed.

15. The substrate processing apparatus of claim 14, further comprising:
a heater configured to heat the substrate,
and wherein the controller is further configured to control the heater to heat the substrate to a temperature lower than a thermal decomposition temperature of the metal fluoride film in (a).

16. The substrate processing apparatus of claim 15, wherein the controller is further configured to control the heater to heat the substrate to a temperature higher than a reaction temperature of the chlorine-containing gas and the metal fluoride film in (b).

17. A non-transitory computer-readable recording medium storing a program that causes, by a computer, a substrate processing apparatus to perform:
(a) forming a metal fluoride film on a substrate on which a metal oxide film is exposed by supplying a fluorine-containing gas to the substrate and fluoridizing the metal oxide film; and
(b) chloridizing and volatilizing the metal fluoride film by supplying a chlorine-containing gas to the substrate on which the metal fluoride film is formed.

18. The non-transitory computer-readable recording medium of claim 17, wherein the substrate is heated to a temperature lower than a thermal decomposition temperature of the metal fluoride film in (a).

19. The non-transitory computer-readable recording medium of claim 18, wherein the substrate is heated to a temperature higher than a reaction temperature of the chlorine-containing gas and the metal fluoride film in (b).

20. The non-transitory computer-readable recording medium of claim 17, further comprising:
(e) exhausting the chlorine-containing gas supplied to the substrate; and
(f) alternately performing (b) and (e).
